(19) United States
(12) Patent Application Publication
(10) Pub. No.: US 2008/0150132 A1
(43) Pub. Date: Jun. 26, 2008

(54) STACK UP PCB SUBSTRATE FOR HIGH DENSITY INTERCONNECT PACKAGES

(76) Inventors: Tom Hu, Gilbert, AZ (US); Mukul D. Sakalkale, Phoenix, AZ (US); Patricia A. Brusso, Chandler, AZ (US); John Schoenhals, Scottsdale, AZ (US); William Vander Weyst, Gilbert, AZ (US)

Correspondence Address: INTEL/BLAKELY, 1279 OAKMEAD PARKWAY, SUNNYVALE, CA, 94085-4040, US

(21) Appl. No.: 11/614,864

(22) Filed: Dec. 21, 2006

(51) Int. Cl. H05K 7/02; H01L 21/50; H01L 23/488

(52) U.S. Cl. 257/737; 361/807; 438/106; 257/E23.023; 257/E21.499

(57) ABSTRACT

An apparatus including a circuit device and a composite package substrate. A system including a computing device including a microprocessor, the microprocessor coupled to a printed circuit board through a first substrate and a second substrate, wherein the second substrate includes a thickness that is less that a thickness of the first substrate. An apparatus including a first package substrate for a circuit device to be mounted thereon and a second substrate coupled to the first substrate, wherein the second substrate includes a thickness that is less than a thickness of the first substrate. A method including coupling a first substrate to a second substrate and coupling a circuit device to the first substrate, wherein the first substrate includes a surface area that is less than a surface area of the second substrate.

### BACKGROUND

1. Field

Integrated circuit packaging.

2. Description

Integrated circuit chips or die are typically assembled into a package that is soldered to a printed circuit board. A chip or die may have contacts on one surface that are used to electrically connect the chip or die to a package substrate and correspondingly an integrated circuit to the package substrate. Accordingly, a suitable package substrate may have corresponding contacts on one surface. One way a number of contacts of a chip or die are connected to contacts of a package substrate are with solder ball contacts in, for example, a controlled collapse chip connect (C4) process. The package substrate typically also has a number of contacts on an opposite surface that are used to electrically connect the package substrate to a printed circuit board. One way this may be done is through solder connections such as a ball grid array (BGA).

Current industry practice is to replace traditional lead-based solder joints with lead-free solder joints. The lead-free transition has lowered the printed circuit board (PCB) materials margin by transferring more solder joint stress into the board. Another trend is the densification of package contacts also known as pitch reduction. With pitch reduction typically comes smaller PCB contact pads. Smaller PCB contact pads mean the stress on the pads is concentrated on a smaller surface area. This increases the possibility of pad cratering. Pad cratering is board laminate cracking starting from an edge of a pad at a pad-laminate interface, propagating under the pad. Similar cratering may occur instead or additionally on the package side of the solder connection (i.e., at the package substrate). Pad cratering is primarily caused by mechanical stresses within the solder joints. These stresses are influenced by PCB material (lead-free transition) and PCB contact size (pitch reduction) and are typically greatest near package corners.

### BRIEF DESCRIPTION OF THE DRAWINGS

Features, aspects, and advantages of embodiments will become more thoroughly apparent from the following detailed description, appended claims, and accompanying drawings in which:

FIG. 1 shows a package connected to a motherboard and a computer system.

FIG. 2 shows a schematic top view of a portion of the composite package substrate of FIG. 1 with schematic illustrations of similar stress.

FIG. 3 shows an exploded side view of the composite package substrate of FIG. 1 and illustrates the contact points associated with each substrate of the composite package substrate.

FIG. 4 shows the composite package substrate of FIG. 1 and illustrates the contact points associated with the composite package substrate.

### DETAILED DESCRIPTION

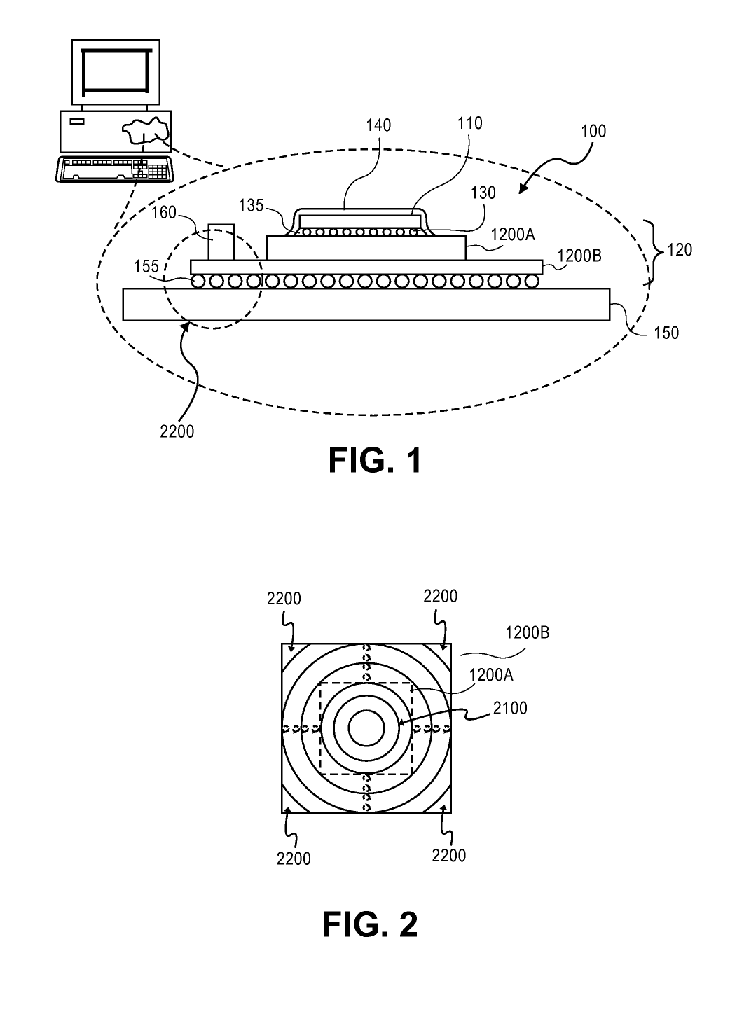

FIG. 1 shows an embodiment of an electronic assembly including a package connected to a printed circuit board (PCB). The electronic assembly may be part of an electronic system such as a computer (e.g., desktop, laptop, hand-held, server, internet appliance, etc.), a wireless communication device (e.g., cellular phone, cordless phone, pager), a computer-related peripheral (e.g., printer, scanner, monitor), and entertainment device (e.g., television, radio, stereo, tape player, compact disc player, video cassette recorder, Motion Picture Experts Group, audio writer 3 (MP3) player and the like. FIG. 1 shows electronic assembly 100 that is part of a desktop computer.

In the embodiment shown in FIG. 1, electronic assembly 100 includes chip or die 110, having a number of circuit devices formed thereon and therein. Chip 110 is mechanically and electrically connected to composite package substrate 120. Chip 110 is electrically connected to composite package substrate 120, in this embodiment, through lead-free solder connections 130 (shown as solder balls) between corresponding contact points (e.g., conductive pads) on chip 110 and composite package substrate 120, respectively. Disposed between chip 110 and composite package substrate 120 is underfill formulation 135 such as an epoxy. Disposed over chip 110 and composite package substrate 120 is molding compound 140 such as an epoxy.

FIG. 1 shows composite package substrate 120 connected to printed circuit board (PCB) 150 in a ball grid array (BGA) type configuration. PCB 150 is, for example, a motherboard or other circuit board. Composite package substrate 120 is connected to PCB 150 through, for example, lead-free solder connections 155 at corresponding contact points (e.g., conductive pads) of composite package substrate 120 and PCB 150, respectively. Representatively, a lead-free solder for a BGA application is tin-silver-copper (Sn—Ag—Cu) (Ag is 0.3 to 0.4 wt. % and Cu is ˜0.5 wt. %) may be formed using 230° C. to 250° C. as a peak reflow temperature. PCB 150 may include other components, possibly connected to chip 110 through traces embedded in PCB 150. Representatively, FIG. 1 shows unit 160 that is, for example, a memory device, a power device or other device.

Referring to FIG. 1, composite package substrate 120 includes substrate 1200A and substrate 1200B with electrical interconnections running between the substrates to establish a number of contact points (e.g., conductive pads) on a surface of substrate 1200A (a top or device side surface as viewed) and a surface of substrate 1200B (a bottom or PCB side surface as viewed). Composite package substrate 120, in one embodiment, serves to connect chip 110 to PCB 150. Thus, composite package substrate 120 has a number of conductive interconnects therethrough with contact pads on each of a device side and a PCB side. In one embodiment, substrate 1200A as a cross-sectional area sufficiently large enough to accommodate chip 110 (e.g., a cross-sectional area larger than a cross-sectional area of chip 110). Substrate 1200B has a cross-sectional area that is greater than a cross-sectional area of substrate 1200A.

Substrate 1200B includes a number of contact points on one surface (a bottom or PCB surface as viewed) to connect composite package substrate 120 to printed circuit board 150 through, for example, solder connections. Thus, the pitch of contact points on a PCB side of substrate 1200B corresponds to a contact pitch of PCB 150.

In one embodiment, substrate 1200A is a fiberglass impregnated laminate having a thickness on the order of about one millimeter. Substrate 1200B may be of a similar material as substrate 1200A with a reduced thickness to render substrate 1200B more flexible than substrate 1200A. In one embodiment, a suitable thickness for substrate 1200B is on the order of about 0.2 millimeters. Alternatively, substrate 1200B may be a material that is different than substrate 1200A. For example, where substrate 1200A is a fiberglass impregnated laminate, substrate 1200B may be a flexible circuit material such as a polyimide material.

Composite package substrate 120 recognizes that the package soldered joint stress is generally not equally distributed across the package substrate. The highest stresses tend to occur at the edges and corner of the package substrate. FIG. 2, for example, illustrates a schematic top view of substrate 1200B of composite package substrate 120. As illustrated in FIG. 2, areas of substrate 1200B denoted by circular regions 2100 tend to experience a roughly equal stress while areas 2200 at the edges and corners tend to experience the highest stress. By making substrate 1200B of a relatively flexible material, stresses at areas 2200 (e.g., the corners and outer rows and columns of substrate 1200B may be reduced.

In one embodiment, the contact points (pads) on a PCB side of substrate 1200B are arranged in a row and column configuration occupying a large percentage of the surface area of the PCB side surface of substrate 1200B. FIG. 1 shows a single row or column. In one embodiment, substrate 1200B has a surface area that is larger than substrate 1200A. Representatively, substrate 1200B has a surface area such that when viewed from a device side, substrate 1200A has a surface area that encompasses all but the last four rows and columns of contact points of substrate 1200B. Thus, the outermost contact points (e.g., conductive pads) of substrate 1200B (designated by arrow 2200 in FIG. 1) experience less stress due to the flexibility of substrate 1200B relative to contact points (i.e., solder connections) that are within an area occupied by both substrate 1200A and substrate 1200B.

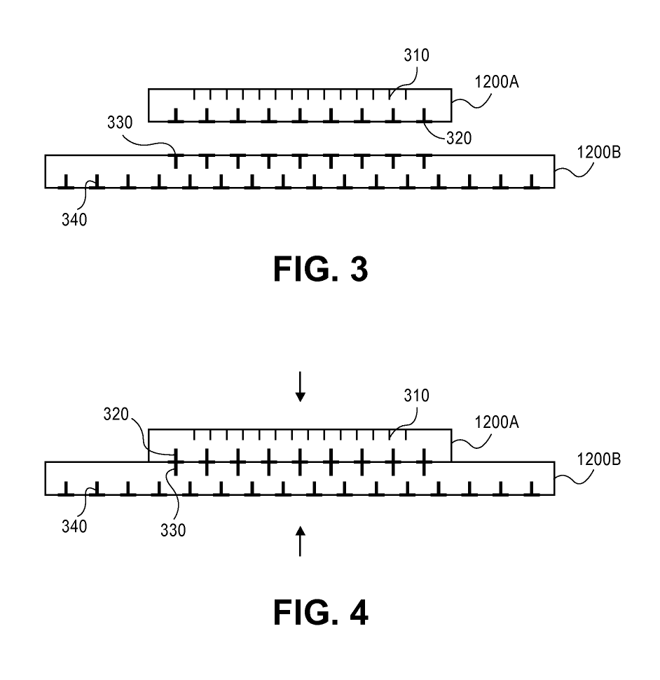

FIG. 3 and FIG. 4 show representations of the connection between substrate 1200A and substrate 1200B. Representatively, substrate 1200A includes a first side having a number of contact points (conductive pads) 310 on a surface thereof to accommodate contact pads on a chip, such as a microprocessor, through a C4 bonding configuration using, for example, lead-free solder connections (see connections 130 in FIG. 1). Substrate 1200A has a number of interconnections running therethrough (from a first device side to a second opposite side) and includes contact points 320 on a second side of the substrate (a side opposite the device side). Contact points 320 may have a pitch that is greater than a pitch of contact points 310.

Referring to substrate 1200B, FIG. 3 and FIG. 4 shows a first side of substrate 1200B having a number of contact points 330 corresponding to contact points 320 of substrate 1200A (i.e., having a pitch similar to the pitch of contact points 320). Substrate 1200B has a number of interconnections running from a first side to a second PCB side to contact points 340 that may or may not have a contact pitch greater than a contact pitch of contact points 330. Contact points 340 on a second side of substrate 1200B correspond to a contact pitch of a printed circuit board to which substrate 1200B may be affixed through solder connections such as lead-free solder connections (see solder connection 155 connecting substrate 1200B to PCB 150 in FIG. 1).

In one embodiment, contact points 320 of substrate 1200A are connected to contact points 330 of substrate 1200B through gold plated bumps that are formed on either or both of contact points 320 and contact points 330. Representatively, having the plated bumps formed on the contact points, substrate 1200A and substrate 1200B are forced together with the contact points aligned and a thermal or ultrasonic force is used to bind the substrates together to form composite package substrate 120.

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. An apparatus comprising:
a circuit device;
a first substrate comprising a first plurality of contact points on a first surface corresponding to contact points on the circuit device; and
a second substrate coupled to a second surface of the first substrate, such that the first substrate is disposed between the circuit device and the second substrate, the second substrate comprising a plurality of contact points configured to electrically couple the circuit device to a printed circuit board.

2. The apparatus of claim 1, wherein the second substrate comprises a thickness that is less than a thickness of the first substrate.

3. The apparatus of claim 1, wherein the second surface of the first substrate comprises a plurality of second contact points electrically coupled to the plurality of contact points of the second substrate.

4. The apparatus of claim 1, wherein the first substrate comprises a surface area that is less than a surface area of the second substrate.

5. The apparatus of claim 1, further comprising a plurality of lead-free solder bumps disposed on the plurality of contact points of the second substrate.

6. The apparatus of claim 1, wherein the circuit device comprises a microprocessor chip.

7. A system comprising:
a computing device comprising a microprocessor, the microprocessor coupled to a printed circuit board through a first substrate and a second substrate, the first substrate disposed between the microprocessor and the second substrate, wherein the second substrate comprises a thickness that is less than a thickness of the first substrate.

8. The system of claim 7, wherein the first substrate comprises a surface area that is less than a surface area of the second substrate.

9. The apparatus of claim 7, wherein the second substrate is coupled to the printed circuit board through a plurality of lead-free solder bumps.

10. An apparatus comprising:
a first substrate comprising a first plurality of contact points on a first surface corresponding to contact points for a circuit device to be mounted thereon; and
a second substrate comprising a first surface coupled to a second surface of the first substrate and a second surface comprising a plurality of contact points configured to electrically couple the second substrate to a printed circuit board, wherein the second substrate comprises a thickness that is less than a thickness of the first substrate.

11. The apparatus of claim 10, wherein the second surface of the first substrate comprises a plurality of second contact points electrically coupled to the plurality of contact points of the second substrate.

12. The apparatus of claim 10, wherein the first substrate comprises a surface area that is less than a surface area of the second substrate.

13. A method comprising:
coupling a first substrate to a second substrate, the first substrate comprising a first plurality of contact points on a first surface and the second substrate comprising a first surface coupled to a second surface of the first substrate; and
coupling a circuit device to the first plurality of contacts on the first substrate,
wherein the first substrate comprises a surface area that is less than a surface area of the second substrate.

14. The method of claim 13, further comprising coupling a circuit device to the first substrate.

15. The method of claim 14, further comprising coupling the second substrate to a printed circuit board using lead-free solder.
